(19) United States
(12) Patent Application Publication
(10) Pub. No.: US 2024/0194654 A1
(43) Pub. Date: Jun. 13, 2024

(54) DISPLAY PANEL AND DISPLAY APPARATUS

(71) Applicant: WUHAN TIANMA MICRO-ELECTRONICS CO., LTD., Wuhan (CN)

(72) Inventor: Linshan GUO, Wuhan (CN)

(73) Assignee: WUHAN TIANMA MICRO-ELECTRONICS CO., LTD., Wuhan (CN)

(21) Appl. No.: 18/582,008

(22) Filed: Feb. 20, 2024

(30) Foreign Application Priority Data
Aug. 3, 2023 (CN) 202310975135.9

(51) Int. Cl. H01L 25/075; H01L 27/12; H01L 33/50

(52) U.S. Cl. CPC H01L 25/0753; H01L 33/507; H01L 27/124

(57) ABSTRACT

The present disclosure provides a display panel and a display apparatus. The display panel includes a color filter unit. The color filter unit includes a first-color color filter unit and a second-color color filter unit, and the first-color color filter unit is located at a side of the second-color color filter unit adjacent to a substrate. The first-color color filter unit is a blue color filter. The blue color filter is disposed on the side of the second-color color filter unit adjacent to the substrate. Compared with the second-color color filter unit, the blue color filter is preferentially coated, exposed, developed, and ultraviolet cured. Then, in a subsequent process of making the display panel, when the second-color color filter unit is ultraviolet cured, secondary ultraviolet irradiation can be performed on the blue color filter formed in an early stage, which can enhance film adhesion of the blue color filter.

### CROSS-REFERENCE TO RELATED DISCLOSURE

The present disclosure claims priority to Chinese Patent Application No. 202310975135.9, filed on Aug. 3, 2023, the content of which is incorporated herein by reference in its entirety.

### TECHNICAL FIELD

The present disclosure relates to the technical field of displays, and in particular, to a display panel and a display apparatus.

### BACKGROUND

An organic light-emitting diode (OLED) display technology has been applied in flexible display screens due to its advantages of self-illumination, a low power consumption, a light weight, and no liquid crystal flow layer. A flexible OLED display screen typically includes a substrate-based thin-film transistor (TFT) layer, a light-emitting layer, a packaging layer based on a multilayer thin film, and a circular polarizer (POL). For a top-emitting OLED display screen, the circular POL can reduce reflectivity of ambient light, increase a contrast ratio, and improve outdoor readability of the OLED display screen, but also loses about 58% of output light. In addition, a large thickness and a brittle texture thereof limit the development of a dynamic bendable display product.

Replacing a POL with a color filter (CF) is classified as a POL-less technology, which not only reduces a thickness of a functional layer from approximately 100 μm to approximately 5 μm, but also can increase a light output rate of an OLED from 42% to 60%.

The circular POL is replaced with a black matrix and a filter structure to reduce luminous flux of ambient light entering a display panel. However, the black matrix and the filter structure still have certain reflectivity, which affects viewing experience of the display panel.

### SUMMARY

One aspect of the present disclosure provides a display panel. The display panel includes a substrate, an array layer, a light-emitting layer, and a color filtering layer. The array layer is located at a side of the substrate. The light-emitting layer is located at a side of the array layer away from the substrate, and includes multiple light-emitting units. The color filtering layer is located at a side of the light-emitting layer away from the substrate. The filtering layer includes a color filter unit, and the color filter unit corresponds to the light-emitting unit. The color filter unit includes a first-color color filter unit and a second-color color filter unit, and the first-color color filter unit is located at a side of the second-color color filter unit adjacent to the substrate. The first-color color filter unit is a blue color filter unit.

Another aspect of the present disclosure further provides a display apparatus. The display apparatus includes a display panel. The display panel includes a substrate, an array layer, a light-emitting layer, and a color filtering layer. The array layer is located at a side of the substrate. The light-emitting layer is located at a side of the array layer away from the substrate, and includes multiple light-emitting units. The color filtering layer is located at a side of the light-emitting layer away from the substrate. The filtering layer includes a color filter unit, and the color filter unit corresponds to the light-emitting unit. The color filter unit includes a first-color color filter unit and a second-color color filter unit, and the first-color color filter unit is located at a side of the second-color color filter unit adjacent to the substrate. The first-color color filter unit is a blue color filter unit.

### BRIEF DESCRIPTION OF DRAWINGS

FIG. 1 is a schematic diagram of a display panel according to an embodiment of the present disclosure;

FIG. 2 is a cross-sectional view of the display panel along line A₁-A₂ shown in FIG. 1 according to an embodiment of the present disclosure;

FIG. 3 is a cross-sectional view of the display panel along line A₁-A₂ shown in FIG. 1 according to another embodiment of the present disclosure;

FIG. 4 is a cross-sectional view of the display panel along line A₁-A₂ shown in FIG. 1 according to another embodiment of the present disclosure;

FIG. 5 is a cross-sectional view of the display panel along line A₁-A₂ shown in FIG. 1 according to another embodiment of the present disclosure;

FIG. 6 is a cross-sectional view of the display panel along line A₁-A₂ shown in FIG. 1 according to another embodiment of the present disclosure;

FIG. 7 is a cross-sectional view of the display panel along line A₁-A₂ shown in FIG. 1 according to another embodiment of the present disclosure;

FIG. 8 is a cross-sectional view of the display panel along line A₁-A₂ shown in FIG. 1 according to another embodiment of the present disclosure;

FIG. 9 is a cross-sectional view of the display panel along line A₁-A₂ shown in FIG. 1 according to another embodiment of the present disclosure;

FIG. 10 is a cross-sectional view of the display panel along line A₁-A₂ shown in FIG. 1 according to another embodiment of the present disclosure;

FIG. 11 is a cross-sectional view of the display panel along line A₁-A₂ shown in FIG. 1 according to another embodiment of the present disclosure;

FIG. 12 is a cross-sectional view of the display panel along line A₁-A₂ shown in FIG. 1 according to another embodiment of the present disclosure;

FIG. 13 is a cross-sectional view of the display panel along line A₁-A₂ shown in FIG. 1 according to another embodiment of the present disclosure;

FIG. 14 is a cross-sectional view of the display panel along line A₁-A₂ shown in FIG. 1 according to another embodiment of the present disclosure;

FIG. 15 is a cross-sectional view of the display panel along line A₁-A₂ shown in FIG. 1 according to another embodiment of the present disclosure;

FIG. 16 is a cross-sectional view of the display panel along line A₁-A₂ shown in FIG. 1 according to another embodiment of the present disclosure;

FIG. 17 is a cross-sectional view of the display panel along line A₁-A₂ shown in FIG. 1 according to another embodiment of the present disclosure;

FIG. 18 is a cross-sectional view of the display panel along line A₁-A₂ shown in FIG. 1 according to another embodiment of the present disclosure;

FIG. 19 is a cross-sectional view of the display panel along line A₁-A₂ shown in FIG. 1 according to another embodiment of the present disclosure;

FIG. 20 is a cross-sectional view of the display panel along line A₁-A₂ shown in FIG. 1 according to another embodiment of the present disclosure;

FIG. 21 is a schematic diagram of a display panel according to an embodiment of the present disclosure;

FIG. 22 is a cross-sectional view of the display panel along line B1-B2 shown in FIG. 1 according to an embodiment of the present disclosure; and

FIG. 23 is a schematic diagram of a display apparatus according to an embodiment of the present disclosure.

### DESCRIPTION OF EMBODIMENTS

To make the objectives, features, and advantages of the present disclosure more comprehensible, the present disclosure is described in detail below with reference to the drawings and specific embodiments.

The following provides detailed description of features and exemplary embodiments of various aspects of the present disclosure. In the detailed description below, many specific details are illustrated to provide a comprehensive understanding of the present disclosure. However, it should be appreciated by those of skill in the art that the present disclosure may be implemented without some of these specific details. The following embodiments are described only to provide a better understanding of the present disclosure by illustrating examples of the present disclosure. In the accompanying drawings and the following description, at least some well-known structures and techniques are not described to avoid unnecessary ambiguity of the present disclosure. Moreover, for clarity, sizes of some structures may have been exaggerated. In addition, the described features, structures, or characteristics below may be incorporated into one or more embodiments in any suitable manner.

In addition, for the sake of understanding and ease of description, a size and a thicknesses of each configuration shown in the figure are arbitrarily shown, but the present disclosure is not limited thereto. In the drawings, thicknesses of a layer, a film, a panel, and a region are exaggerated for clarity. In the figure, thicknesses of some layers and regions are exaggerated for a better understanding and ease description.

In addition, unless explicitly described to the contrary, the term “including” or “comprising” will be understood as implicitly including the stated element, without excluding any other element.

A color filter unit is cured under ultraviolet light (i.e., ultraviolet cured) after being coated and exposed. A blue color filter has a relatively high (ultraviolet) transmittance in a short wave band, resulting in a poor ultraviolet curing effect, poor relative adhesion between film layers, and even film peeling in a severe case. This causes a crack on a display panel, and affects a preparation yield of the display panel. In the present disclosure, the blue color filter is disposed on a side of a second-color color filter unit adjacent to a substrate. Compared with the second-color color filter unit, the blue color filter is preferentially coated, exposed, developed, and ultraviolet cured. Then, in a subsequent process of making the display panel, when the second-color color filter unit is ultraviolet cured, secondary ultraviolet irradiation can be performed on the blue color filter formed in an early stage, which can enhance film adhesion of the blue color filter, reduce a risk of generating the crack, shorten curing time of the blue color filter, and improve curing efficiency.

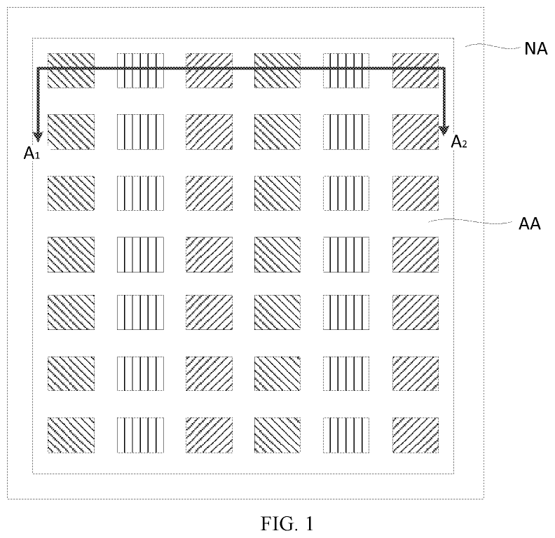

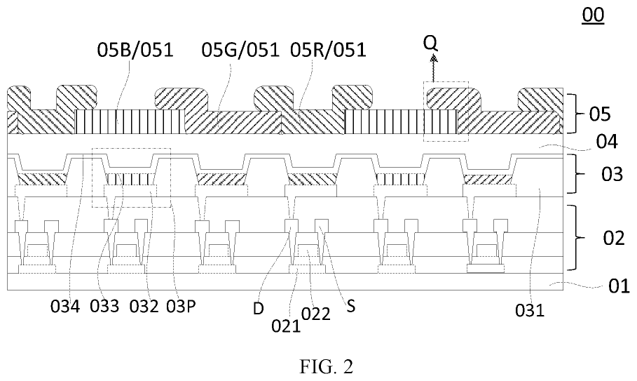

FIG. 1 is a schematic diagram of a display panel according to an embodiment of the present disclosure. FIG. 2 is a cross-sectional view of the display panel along line A₁-A₂ shown in FIG. 1 according to an embodiment of the present disclosure. As shown in FIG. 1 and FIG. 2, the display panel 00 includes a display region AA and a non-display region NA that at least partially surrounds the display region AA. The display panel 00 includes a substrate 01, an array layer 02, a light-emitting layer 03, and a color filtering layer 05. The array layer 02 is located at a side of the substrate 01, and the light-emitting layer 03 is located at a side of the array layer 02 away from the substrate 01. The light-emitting layer includes multiple light-emitting units 03P. The color filtering layer 05 is located at a side of the light-emitting layer 03 away from the substrate 01, and includes multiple color filter units 051. The light-emitting unit 03P corresponds to the color filter unit 051.

In an embodiment of the present disclosure, the array layer 02 includes a TFT that includes an active layer 021, a gate 022, and a source/drain S/D. The TFT includes a low temperature poly-silicon (LTPS) transistor and/or an Indium Gallium Zinc Oxide (IGZO) transistor. In an embodiment of the present disclosure, the light-emitting layer 03 includes an anode 032, a light-emitting functional layer 033, and a cathode 034. In an embodiment of the present disclosure, a light-emitting unit generally includes light-emitting elements that emit light of different colors. For example, the light-emitting unit 03P includes a blue light-emitting element that emits blue light, a green light-emitting element that emits green light, and a red light-emitting element that transmits red light. In an embodiment of the present disclosure, the display panel 00 further includes a pixel definition layer 031 that includes multiple grooves. The light-emitting units are formed at the grooves.

Still referring to FIG. 2, the color filter unit 051 includes a first-color color filter unit 05B and a second-color color filter unit 05G. The first-color color filter unit 05B is located at a side of the second-color color filter unit 05G adjacent to the substrate 01. The first-color color filter unit 05B is a blue color filter. It should be noted that the first-color color filter unit 05B is located at the side of the second-color color filter unit 05G adjacent to the substrate 01. This mainly indicates that the blue color filter is disposed prior to color filters of other colors during preparation. Due to this preparation sequence, the blue color filter 05B is located between the substrate 01 and a color filter unit 05G of another color in some locations of the display panel 00 (such as in a region Q shown in FIG. 2). Because the color filter unit is coated or printed on large area and then patterned during preparation, the first-color color filter unit and the second-color color filter unit may be disposed separately and do not overlap each other in the embodiments. However, provided that the first-color color filter unit 05B is located at the side of the second-color color filter unit 05G adjacent to the substrate 01, in other words, the blue color filter 05B is located at a side of the color filter unit of another color adjacent to the substrate 01, it can be confirmed that the blue color filter should be coated first in a preparation process.

The color filter unit is ultraviolet cured after being coated and exposed. However, the applicant finds that the blue color filter has relatively high (ultraviolet) transmittance in a short wave band, resulting in a poor ultraviolet curing effect. The blue color filter with a poor curing effect results in a poor relative adhesion effect between film layers, and even film peeling in a severe case. This causes a crack on the display panel, and affects a preparation yield of the display panel. In the present disclosure, the blue color filter 05B is disposed on the side of the second-color color filter unit 05G adjacent to the substrate 01. Compared with the second-color color filter unit 05G, the blue color filter 05B is preferentially coated, exposed, developed, and ultraviolet cured. Then, in a subsequent process of making the display panel, when the second-color color filter unit is ultraviolet cured, secondary ultraviolet irradiation can be performed on the blue color filter 05B formed in an early stage, which can enhance film adhesion of the blue color filter, reduce a risk of generating the crack, shorten curing time of the blue color filter and a production time cost, and improve curing efficiency.

On one hand, the display panel provided in the present disclosure replaces a traditional POL with a color film layer, which not only reduces a thickness of the display panel, but also increases light transmittance and enhances brightness of the entire display panel. On the other hand, the blue color filter is disposed on the side of the second-color color filter unit adjacent to the substrate. Compared with the second-color color filter unit, the blue color filter is preferentially coated, exposed, developed, and ultraviolet cured. Then, in the subsequent process of making the display panel, when the second-color color filter unit is ultraviolet cured, the secondary ultraviolet irradiation can be performed on the blue color filter formed in the early stage. This can enhance the film adhesion of the blue color filter, reduce the risk of generating the crack, shorten the curing time of the blue color filter, and improve the curing efficiency.

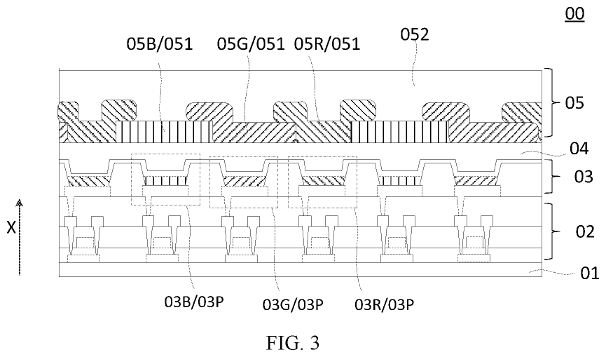

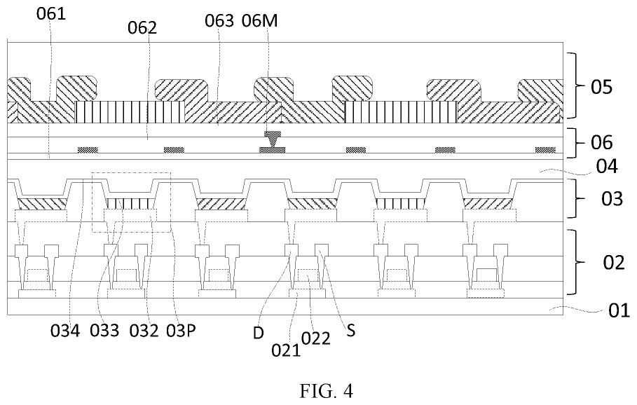

FIG. 3 is a cross-sectional view of the display panel along line A₁-A₂ shown in FIG. 1. FIG. 4 is a cross-sectional view of the display panel along line A₁-A₂ shown in FIG. 1. As shown in FIG. 3, the color filter unit 051 corresponds to the light-emitting unit 03P. In a direction X perpendicular to the substrate, one light-emitting unit 03P corresponds to one color filter unit 051, which means that the light-emitting unit 03P at least partially overlaps the corresponding color filter unit 051. For example, the first-color color filter unit 05B corresponds to a first-color light-emitting unit 03B, and the second-color color filter unit 05G corresponds to a second-color light-emitting unit 03G, and a third-color color filter unit 05R corresponds to a third-color light-emitting unit 03R; and/or, one color filter unit 03P corresponds to at least two light-emitting units 05, for example, two adjacent green light-emitting units correspond to one color filter unit.

In the direction X perpendicular to the substrate, the light-emitting unit 03P at least partially overlaps the color filter unit 051. In other optional embodiments, an orthogonal projection of the color filter unit 051 on the substrate 01 covers an orthogonal projection of the light-emitting unit 03P on the substrate 01, and area of the color filter unit 051 is greater than area of the light-emitting unit 03P corresponding to the color filter unit 051. In an embodiment of the present disclosure, when a same light-emitting unit 031P corresponds to at least two light-emitting units 03P, colors of the at least two color filter units may be the same or different.

It should be noted that in the accompanying drawings of the present disclosure, the color filter unit adopts a same padding pattern as the corresponding light-emitting unit, only for a purpose of describing a relationship between the color filter unit and the light-emitting unit, instead of making any limitation.

Still referring to FIG. 3 and FIG. 4, the color filtering layer 05 of the display panel 00 includes a color filter dielectric layer 052 made of an organic or inorganic material. When the color filter dielectric layer 052 is made of an organic material, the color filter dielectric layer 052 has certain flatness performance, providing a flat surface for subsequent film layer preparation. When the color filter dielectric layer 052 is made of the inorganic material, due to good compactness of the inorganic material, the color filter dielectric layer 052 can effectively protect the color filter unit and prevents water vapor affecting the color filter unit. The display panel 00 further includes a touch layer 06. The touch layer 06 includes a touch base material layer 061, touch metal 06M, a touch insulation layer 052, and a touch dielectric layer 063. The touch base material layer 061 and the touch insulation layer 052 are made of an inorganic material, and the touch dielectric layer 063 may be made of the inorganic or organic material. In an embodiment of the present disclosure, the touch layer 06 may not include the touch dielectric layer 063. In this case, the color filter unit 051 directly contacts the touch metal 06M below, shortening a vertical distance between the color filter unit 051 and the light-emitting unit 031, improving a light output effect of the light-emitting unit, and improving a viewing angle of light output of the light-emitting unit.

The display panel 00 further includes a thin-film packaging layer 04 located between the color filtering layer 05 and the light-emitting layer 03. In an embodiment of the present disclosure, the thin-film packaging layer 04 may include one, two, or more film layers, and may include alternately disposed organic and inorganic layers. In the display panel provided in this embodiment, as a flexible substrate, the substrate 01 is bendable. In an embodiment of the present disclosure, the thin-film packaging layer 04 has good bending performance. The display panel provided in this embodiment can be bent and folded. A specific material and a film layer structure of the thin-film packaging layer 04 are not specifically limited in this embodiment.

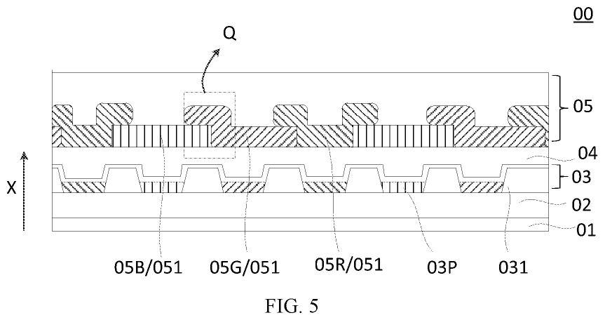

FIG. 5 is a cross-sectional view of the display panel along line A₁-A₂ shown in FIG. 1. As shown in FIG. 5, the color filtering layer 05 includes a first region Q located between adjacent light-emitting units 03P. In the first direction X, the first region Q overlaps the pixel definition layer. Along the first direction X, there are at least overlapping color filter units 051 of different colors in the first region Q, in other words, the color filter units of different colors in the first direction X at least partially overlap each other. The first direction X is perpendicular to the substrate 01 and points to a light exit surface of the display panel 00. The first region Q is a divided region of the color filtering layer 05. When the first-color color filter unit 05B and the second-color color filter unit 05G overlap in the first region Q, because the first-color color filter unit can only make first-color light penetrate, and the second-color color filter unit can only make second-color light penetrate, light emitted by one light-emitting unit 031 cannot penetrate through both the first-color color filter unit 05B and the second-color color filter unit 05G. This means that light emitted by a single light-emitting unit 03P cannot penetrate through the first region Q. The overlapped first-color color filter unit 05B and second-color color filter unit 05G can effectively prevent crosstalk of light output by adjacent light-emitting units of different colors. In addition, the first region Q can reduce reflection of ambient light into a human eye through the anode or the cathode, improve an anti-reflection capability, and improve a display effect. Replacing the black matrix in the prior art with overlapping color filter units can save a mask and reduce its cost.

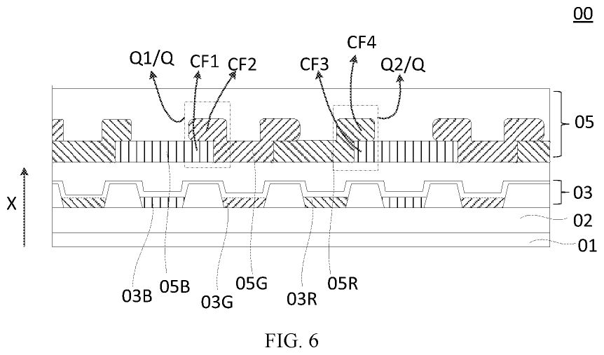

FIG. 6 is a cross-sectional view of the display panel along line A₁-A₂ shown in FIG. 1. The light-emitting unit includes the first-color light-emitting unit 03B, the second-color light-emitting unit 03G, and the third-color light-emitting unit 03R that are of different colors. The color filter unit 051 further includes the third-color color filter unit 05R corresponding to the third-color light-emitting unit 03R. The first region Q includes overlapping color filter units 051 of two colors. The first region Q includes a first sub-region Q1 and a second sub-region Q2. The first sub-region Q1 is located between the first-color light-emitting unit 03B and the second-color light-emitting unit 03G, and the second sub-region Q2 is located between the first-color light-emitting unit 03B and the third-color light-emitting unit 03R. The first sub-region Q1 includes a first color sub-filter CF1 and a second color sub-filter CF2 that are of different colors and overlap each other. The second sub-region Q2 includes a third color sub-filter CF3 and a fourth color sub-filter CF4 that are of different colors and overlap each other. At least one of the first color sub-filter CF1 and the second color sub-filter CF2 has a same color as at least one of the third color sub-filter CF3 and the fourth color sub-filter CF4.

As shown in FIG. 6, the first color sub-filter CF1 in the first sub-region Q1 has a same color as the first-color color filter unit 05B, and the third color sub-filter in the second sub-region Q2 has a same color as the first-color color filter unit. In other words, the first color sub-filter CF1 has a same color as the third color sub-filter CF3. The at least one of the first color sub-filter CF1 and the second color sub-filter CF2 has the same color as the at least one of the third color sub-filter CF3 and the fourth color sub-filter CF4, such that multiple overlapping color filter units in the first regions Q are reused. Furthermore, a same material and a same process can be used to prepare a color sub-filter and a color filter unit that have a same color, avoiding an additional process for preparing the color sub-filter in the first region Q, and reducing the cost.

It should be noted that the color sub-filter has the same color as the color filter unit in the present disclosure means that a color of light emitted by a same light-emitting unit after passing through the color sub-filter is the same as a color of light passing through the color filter unit.

In an embodiment of the present disclosure, the first-color color filter unit 05B is the blue color filter, the second-color color filter unit 05G is a green color filter, and the third-color color filter unit 05R is a red color filter.

Still referring to FIG. 6, the first color sub-filter CF1 has a same color as one of the first-color color filter unit 05B and the second-color color filter unit 05G, and the second color sub-filter CF2 has a same color as the third-color color filter unit 05R; and/or the third color sub-filter CF3 has a same color as one of the first-color color filter unit 05B and the third-color color filter unit 05R, and the fourth color sub-filter CF4 has a same color as the second-color color filter unit 05G.

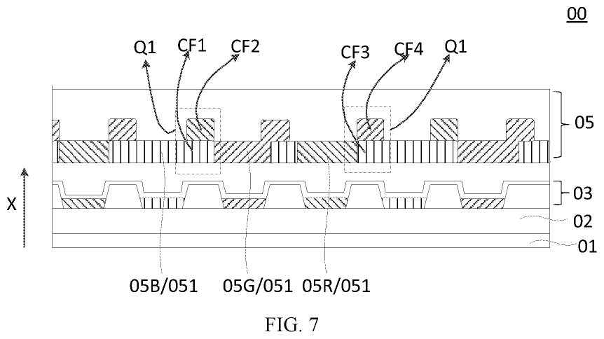

FIG. 7 is a cross-sectional view of the display panel along line A₁-A₂ shown in FIG. 1. As shown in FIG. 7, the first color sub-filter CF1 has the same color as the first-color color filter unit 05B, and a same material and a same process are used to prepare the first color sub-filter CF1 and the first-color color filter unit 05B. The second color sub-filter CF2 has the same color as the third-color color filter unit 05R. A same material and a same process are used to prepare the third color sub-filter CF3 and the first-color color filter unit 05B. A same material and a same process are used to prepare the fourth color sub-filter CF4 and the second-color color filter unit 05G. In this embodiment, the first sub-region Q1 between adjacent first-color light-emitting unit 031B and second-color light-emitting unit 03G includes the second color sub-filter CF2 that has a same color and material as the third-color light-emitting unit 031R. The second color sub-filter CF2 can only make third-color light penetrate. In this embodiment, the second color sub-filter is disposed between the first-color light-emitting unit and the second-color light-emitting to completely block emission of adjacent first-color light and second-color light, achieving a better shading effect.

Still referring to FIG. 7, the first color sub-filter CF1 has a different color from both the first-color color filter unit 05B and the second-color color filter unit 05G; and/or the second color sub-filter CF2 has a different color from both the first-color color filter unit 05B and the second-color color filter unit 05G. In this embodiment, the second color sub-filter CF2 is disposed between the first-color light-emitting unit 05B and the second-color light-emitting unit 05G to completely block the emission of the adjacent first-color light and second-color light, achieving a better shading effect.

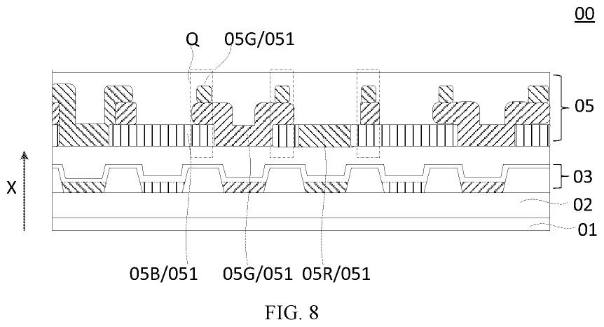

FIG. 8 is a cross-sectional view of the display panel along line A₁-A₂ shown in FIG. 1. As shown in FIG. 8, the first region Q includes three color sub-filters CF whose colors are respectively the same as colors of the first-color color filter unit 05B, the second-color color filter unit 05G, and the third-color color filter unit 05R. Compared with the above embodiments, the first region Q in this embodiment includes the three stacked color sub-filters of different colors. The color sub-filters in the first region are stacked by using a preparation process of the color filter unit, to effectively reduce processes. In addition, compared with two stacked color sub-filter layers, three stacked color sub-filter layers have a better shading effect.

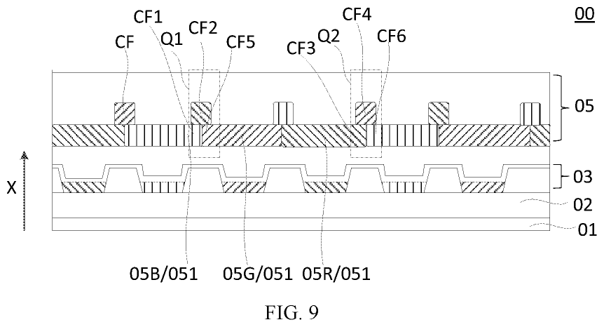

FIG. 9 is a cross-sectional view of the display panel along line A₁-A₂ shown in FIG. 1. In an embodiment of the present disclosure, as shown in FIG. 9, the first sub-region Q1 includes a fifth color sub-filter CF5, and the second sub-region Q2 includes a sixth color sub-filter CF6. In the direction X perpendicular to the substrate 01, the second color sub-filter CF2 overlaps the first color sub-filter CF1, the second color sub-filter CF2 overlaps the fifth color sub-filter CF5, the fourth color sub-filter CF4 overlaps the third color sub-filter CF3, and the fourth color sub-filter CF4 overlaps the sixth color sub-filter CF6. The first color sub-filter CF1 and the first-color color filter unit 05B are color filters of a same color, the fifth color sub-filter CF5 and the second-color color filter unit 05G are color filters of a same color, the second color sub-filter CF2 and the third-color color filter unit 05R are color filters of a same color, the third color sub-filter CF3 and the third-color color filter unit 05R are color filters of a same color, the fourth color sub-filter CF4 and the second-color color filter unit 05G are color filters of a same color, and the sixth color sub-filter CF6 and the first-color color filter unit 05B are color filters of a same color. The first color sub-filter CF1 and the fifth color sub-filter CF5 have a same color as the color filter unit adjacent to the first region Q. In this way, the first-color color filter unit and the first color sub-filter can be prepared by using a same process, and the fifth color sub-filter and the second-color color filter unit can be prepared by using a same process, saving a preparation cost. In addition, light-emitting units of different light-emitting colors are not blocked by the color sub-filter in the first region due to a process preparation error, thereby ensuring a light output rate and the display effect.

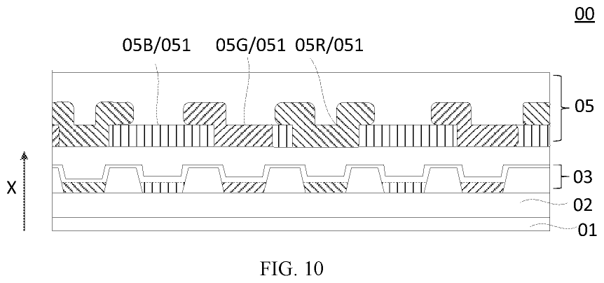

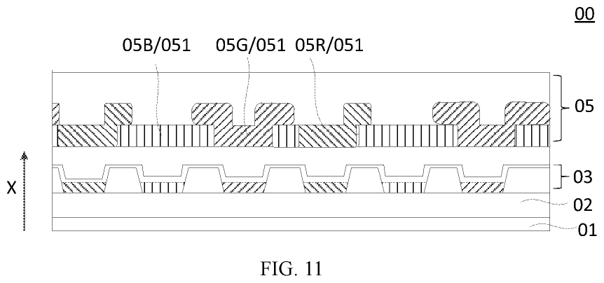

FIG. 10 is a cross-sectional view of the display panel along line A₁-A₂ shown in FIG. 1. FIG. 11 is a cross-sectional view of the display panel along line A₁-A₂ shown in FIG. 1. As shown in FIG. 10 and FIG. 11, in an embodiment of switching the colors of the overlapped color sub-filters in the first region, a same padding pattern is used for the color sub-filter in the first region and a corresponding color filter unit of a same material, which is not described again in the present disclosure. In the present disclosure, the overlapped first-color color filter unit 05B and second-color color filter unit 05G can effectively prevent the crosstalk of the light output by the adjacent light-emitting units of different colors. In addition, the first region Q can reduce the reflection of the ambient light into the human eye through the anode or the cathode, improve the anti-reflection capability, and improve the display effect. Replacing the black matrix in the prior art with the overlapped color filter units can save the mask and reduce its cost.

In an embodiment of the present disclosure, the first color sub-filter has the same color as the third color sub-filter, and the second color sub-filter has the same color as the fourth color sub-filter.

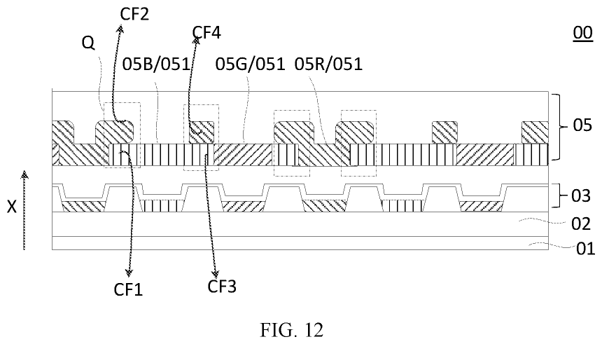

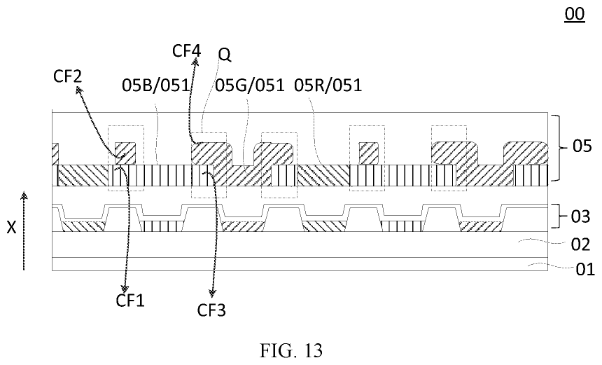

FIG. 12 is a cross-sectional view of the display panel along line A₁-A₂ shown in FIG. 1. FIG. 13 is a cross-sectional view of the display panel along line A₁-A₂ shown in FIG. 1. As shown in FIG. 12 and FIG. 13, in the first region Q, the first color sub-filter CF1 has the same color as the third color sub-filter CF3, and the second color sub-filter CF2 has the same color as the fourth color sub-filter CF4. That is, in the first region Q between light-emitting units of different colors, the overlapped color sub-filters have a same color, which can meet a shading requirement. In addition, this embodiment can convert the color sub-filter and the color filter unit that are prepared by using a same process from large area etching to small area etching, thereby improving etching accuracy and ensuring product quality.

As shown in FIG. 12, the first color sub-filter CF1 has a same color as a blue color filter unit, and the second color sub-filter CF2 has a same color as a red color filter unit. As shown in FIG. 13, the first color sub-filter CF1 has the same color as the blue color filter unit, and the second color sub-filter CF2 has a same color as a green color filter unit. In an embodiment of the present disclosure, the first color sub-filter CF1 has a same color as the red color filter unit, and the second color sub-filter CF2 has the same color as the green color filter unit.

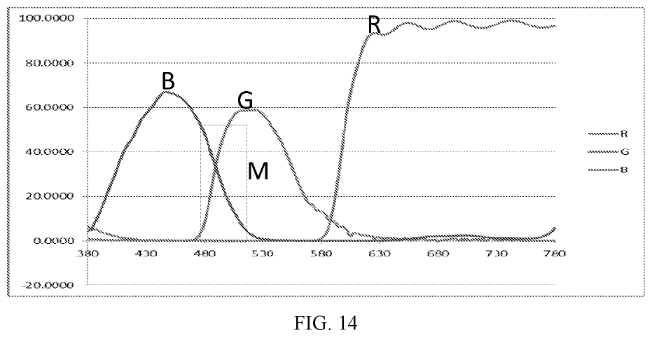

Still referring to FIG. 7, FIG. 9, and FIG. 12, the at least one of the first color sub-filter CF1 and the second color sub-filter CF2 in the first sub-region Q1 in FIG. 7 and FIG. 9 is the red color filter unit. The at least one of the first color sub-filter and the second color sub-filter is the red color filter unit, and/or the at least one of the third color sub-filter and the fourth color sub-filter is the red color filter unit. As shown in FIG. 12, the overlapped color sub-filters in the first region Q include at least one red color filter unit. Compared with the aforementioned embodiments, this embodiment limits use of overlapping color sub-filters of different colors in the first region Q to replace a traditional black shading layer, and at least some of the overlapped color sub-filters in the first region Q include at least the red color filter unit. FIG. 14 shows light transmittance of the color filter units of different colors. As shown in FIG. 14, a horizontal axis represents a wavelength of light, which is in units of nm, and a vertical axis represents a percentage of light penetrating through the color filter unit. As shown in a region M in FIG. 14, light penetrating through the blue color filter unit B and light penetrating through the green color filter unit G have an overlapping region in a wave band from 480 nm to 530 nm. Therefore, when the color sub-filters in the first region are overlapping blue and red color filter units that are made of a same material, it is easy to cause a side leakage of light in the wave band from 480 nm to 530 nm. In this embodiment, at least one of the first color sub-filter and the second color sub-filter is the red color filter unit; and/or, the at least one of the third color sub-filter and the fourth color sub-filter is the red color filter unit. This means that the at least some of the overlapped color sub-filters in the first region Q include at least the red color filter unit, which can effectively avoid the side leakage of the light in the wave band from 480 nm to 530 nm.

In an embodiment of the present disclosure, all the overlapped color sub-filters in the first region Q include at least one red color filter unit.

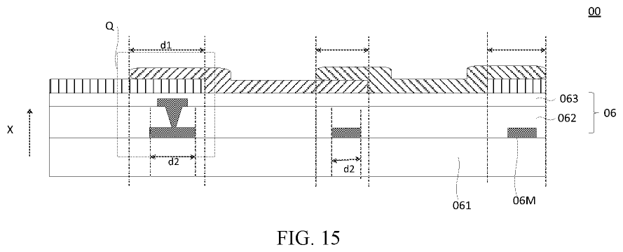

FIG. 15 is a cross-sectional view of the display panel along line A₁-A₂ shown in FIG. 1. As shown in FIG. 15, the display panel 00 further includes the touch layer 06. The touch layer 06 includes the touch base material layer 061, the touch metal 06M, the touch insulation layer 052, and the touch dielectric layer 063. The touch metal 06M includes multiple touch lines 06M located between the light-emitting units (the light-emitting unit is not shown in FIG. 15, and reference may be made to FIG. 4). In the first direction X, the touch line 06M overlaps the first region Q. In the first region Q, an overlapping width of the color filter units of different colors is d1, and a width of the touch line is d2, where d1>d2. In other words, the overlapped width of the color filter units in the first region is greater than the width of the touch line. For the touch line, the overlapped color filter units can prevent the ambient light from being reflected onto a surface of the touch line to cause the metal to be visible. In an embodiment of the present disclosure, the touch line includes a first touch line and a second touch line, and the overlapped width of the color filter units is greater than the larger width of the first touch line and the second touch line.

In an embodiment of the present disclosure, the first-color color filter unit includes a first side surface and a first surface adjacent to a side of the substrate, and an angle formed between a tangent plane of at least a partial region of the first side surface and the first surface is greater than 90°. In an embodiment of the present disclosure, the second-color color filter unit is the green color filter unit. The second-color color filter unit includes a second side surface and a second surface adjacent to a side of the substrate, and an angle formed between a tangent plane of at least a partial region of the second side surface and the second surface is greater than 90°.

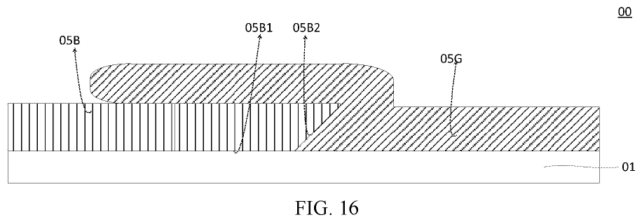

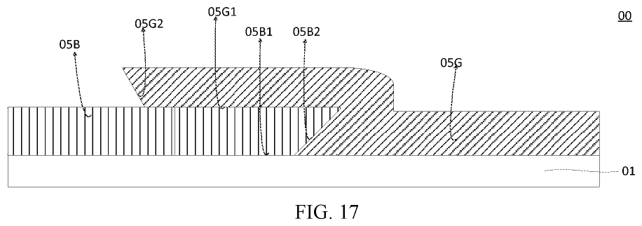

FIG. 16 is a cross-sectional view of the display panel along line A₁-A₂ shown in FIG. 1. FIG. 17 is a cross-sectional view of the display panel along line A₁-A₂ shown in FIG. 1. As shown in FIG. 16, the first-color color filter unit 05B includes the first side surface 05B2 and the first surface 05B1 adjacent to the side of the substrate 01, and the angle formed between the tangent plane of the at least a partial region of the first side surface 05B2 and the first surface 05B2 is greater than 90°. This chamfered shape setting can increase contact area between the first-color color filter unit and the second-color color filter unit, preventing the film layer from being peeled and cracked. As shown in FIG. 17, the second-color color filter unit 05G is the green color filter unit. The second-color color filter unit 05G includes the second side surface 05G2 and the second surface 05G1 adjacent to the side of the substrate 01, and the angle formed between the tangent plane of the at least a partial region of the second side surface 05G2 and the second surface 05G1 is greater than 90°.

FIG. 16 and FIG. 17 omit a film layer structure between the substrate 01 and the color filter unit for a clearer explanation of a shape of the color filter unit.

It should be noted that FIG. 16 and FIG. 17 are exemplary embodiments of setting the shape of the color filter unit. Such shape setting is also applicable to other implementations of the present disclosure.

Still referring to FIG. 2, FIG. 3, FIG. 4, FIG. 5, and FIG. 15, in the first direction X, the first region Q includes the overlapped first-color color filter unit 05R, second-color color filter unit 05G, and third-color color filter unit 05B. The second-color color filter unit 05G is the green color filter unit, and the third-color color filter unit 05R is the red color filter unit. The blue color filter unit is located at a side of the green color filter unit adjacent to the substrate, and the red color filter unit is located at a side of the green color filter unit away from the substrate. That is, a preparation sequence of the color filter units is the blue color filter, then the green color filter, and finally the red color filter. The blue color filter 05B is preferentially coated, exposed, developed, and ultraviolet cured. Then, in the subsequent process of making the display panel, when the second-color color filter unit is ultraviolet cured, the secondary ultraviolet irradiation can be performed on the blue color filter 05B formed in the early stage, which can enhance the film adhesion of the blue color filter and reduce the risk of generating the crack. The red color filter is finally prepared. On one hand, the blue color filter has a strong ultraviolet curing capability. On the other hand, surface reflectivity of the red color filter is low. In the first region, the red color filter serves as an upper film layer of the overlapped color filter units, which can effectively reduce the reflection of the ambient light.

In an embodiment of the present disclosure, the display panel further includes the black matrix located at a side of the first-color color filter unit adjacent to the substrate. Along the first direction, the black matrix overlaps the first region, and a blocking effect is jointly achieved by the black matrix and the overlapped color filter units the first region.

In an embodiment of the present disclosure, the first region includes the overlapped first-color color filter unit and second-color color filter unit. The first-color color filter unit is located at the side of the second-color color filter unit adjacent to the substrate. The first-color color filter unit includes a first through-hole, and the second-color color filter unit includes a second through-hole. An orthographic projection of the second through-hole on the substrate covers an orthogonal projection of the first through-hole on the substrate.

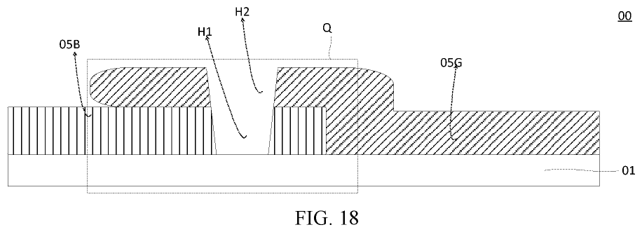

FIG. 18 is a cross-sectional view of the display panel along line A₁-A₂ shown in FIG. 1. As shown in FIG. 18, the first region Q includes the overlapped first-color color filter unit 05B and second-color color filter unit 05G. The first-color color filter unit 05B is located at the side of the second-color color filter unit 05G adjacent to the substrate 01. The first-color color filter unit 05B includes the first through-hole H1, and the second-color color filter unit 05G includes the second through-hole H2. The orthogonal projection of the second through-hole H2 on the substrate 01 covers the orthogonal projection of the first through-hole H1 on the substrate. The first through-hole H1 and the second through-hole H2 jointly form a first hole in the first region Q. The light can penetrate through the first hole. When the display panel includes multiple first holes, the first hole can serve as a sensing hole for sensing, for example, as an imaging hole for fingerprint recognition, and as a sensing hole for capacitance recognition.

In an embodiment of the present disclosure, area of the second through-hole H2 is greater than or equal to area of the first through-hole H1.

In an embodiment of the present disclosure, a maximum width of the second through-hole is smaller than the overlapped width of the color filter units in the first region.

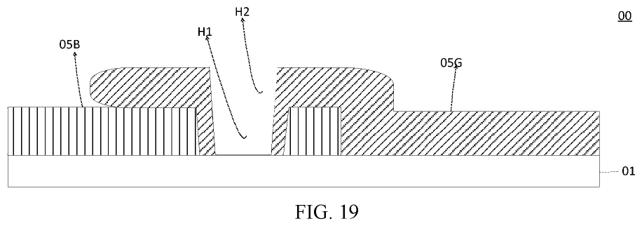

FIG. 19 is a cross-sectional view of the display panel along line A₁-A₂ shown in FIG. 1. As shown in FIG. 19, the second-color color filter unit 05G is at least partially located within the first through-hole H1. In this case, the orthogonal projection of the first through-hole H1 on the substrate 01 is greater than the orthogonal projection of the second through-hole H2 on the substrate 01. In a region where there are still overlapping color filter units in a surrounding region, a blocking capability of the first region can be retained to ensure the anti-reflection ability of the display panel.

In an embodiment of the present disclosure, the first region Q includes the overlapped first-color color filter unit 05B and second-color color filter unit 05G. The first-color color filter unit 05B is located at the side of the second-color color filter unit 05G adjacent to the substrate 01. The first-color color filter unit 05B includes the first through-hole H1, and the second-color color filter unit 05G at least covers the first through-hole H1. The second-color color filter unit is the green color filter unit.

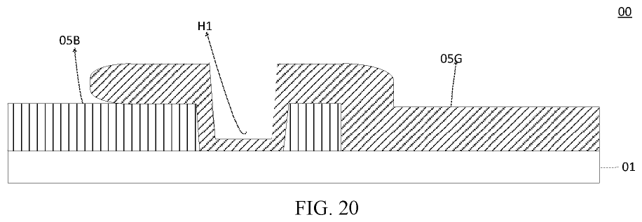

FIG. 20 is a cross-sectional view of the display panel along line A₁-A₂ shown in FIG. 1. As shown in FIG. 20, the first region Q includes the overlapped first-color color filter unit 05B and second-color color filter unit 05G. The first-color color filter unit 05B is located at the side of the second-color color filter unit 05G adjacent to the substrate 01. The first-color color filter unit 05B includes the first through-hole H1, and the second-color filter unit 05G at least covers the first through-hole H1. The second-color color filter unit is the green color filter unit. When only light with a same color as the second-color color filter unit can penetrate through the first through-hole H1, the second-color color filter unit is the green color filter unit. When the first through-hole serves as a fingerprint recognition hole, green light can be received by a photosensitive device for fingerprint recognition. Because the photosensitive device for fingerprint recognition is sensitive to a green light wave band, the photosensitive device has high sensitivity and can effectively ensure accuracy of the fingerprint recognition. In addition, the second-color color filter unit can also serve as a flat layer of the first through-hole, reducing a height difference between a location of the through-hole and a film layer at another location.

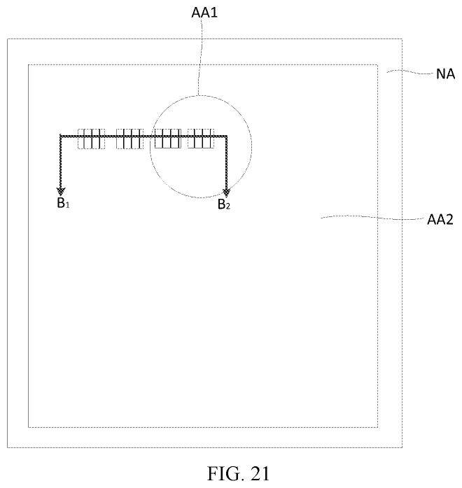

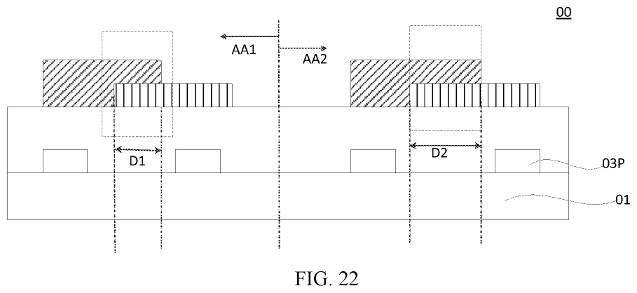

FIG. 21 is a schematic diagram of a display panel according to an embodiment of the present disclosure. FIG. 22 is a cross-sectional view of the display panel along line B1-B2 shown in FIG. 1. As shown in FIG. 21 and FIG. 22, the display panel includes a first display region AA1 and a second display region AA2. Light transmittance of the first display region AA1 is greater than light transmittance of the second display region AA2. The first display region AA1 includes the first region Q, the second display region includes the first region Q, and the first region includes at least two color filter units that overlap each other along the first direction X. An overlapping width of color filters of different colors in the first region Q in the first display region AA1 is D1, and an overlapping width of color filters of different colors in the first region Q in the second display region AA2 is D2, where D1<D2. In this embodiment, a small overlapping width of the color filters of different colors in the first region Q in the first display region AA1 is set to effectively improve the light transmittance of the first display region. Moreover, the overlapped width can be directly used to improve a difference between light transmittance performance of different display regions, which is simple and easy to implement.

It should be noted that an overlapping width of a first-color color filter and a second-color color filter in the first display region is smaller than an overlapping width of a first-color color filter and a second-color color filter in the second display region; and/or, an overlapping width of the first-color color filter and a third-color color filter in the first display region is smaller than an overlapping width of the first-color color filter and a third-color color filter in the second display region; and/or, an overlapping width of the second-color color filter and the third-color color filter in the first display region is smaller than an overlapping width of the second-color color filter and the third-color color filter in the second display region.

In an embodiment of the present disclosure, a distance between adjacent first-color light-emitting unit and second-color light-emitting unit in the first display region is D11, and an overlapping width of a first-color color filter and a second-color color filter that correspond to the first-color light-emitting unit and the second-color light-emitting unit is D12. A distance between adjacent first-color light-emitting unit and second-color light-emitting unit in the second display region is D21, and an overlapping width of a first-color color filter and a second-color color filter that correspond to the first-color light-emitting unit and the second-color light-emitting unit is D22. D12>D11, D22>D21, and D12−D11>D22−D21.

In an embodiment of the present disclosure, the display panel 00 includes the first display region AA1 and the second display region AA2, and the light transmittance of the first display region AA1 is greater than the light transmittance of the second display region AA2. The first display region AA1 includes multiple wiring connection portions. The filtering layer further includes a second region. There are at least overlapping color filter units of different colors in the second region along the first direction, and an orthogonal projection of the second region on the substrate covers the wiring connection portion. The second region is located between adjacent light-emitting units, and the first display region includes multiple wiring connection portions. The overlapped color filter units can be used to shade the wiring connection portion, avoiding visible wiring metal caused by metal reflection. In an embodiment of the present disclosure, the wiring connection portion includes a data cable, a power signal cable, and the like.

Generally, the substrate includes polyimide (PI), which appears faint yellow under the light. When the first display region is used as a photographing region, a photo turns yellow, and photographing quality is affected. In an embodiment of the present disclosure, the second region includes the overlapped first-color color filter unit and the second-color color filter unit, and the first-color color filter unit is located at the side of the second-color color filter unit adjacent to the substrate. A width of the first-color color filter unit is greater than a width of the second-color color filter unit. The first-color color filter unit is the blue color filter unit. Between adjacent light-emitting units, in other words, in the second region, the width of the first-color color filter unit is set to be greater than the width of the second-color color filter unit, which can increase transmittance of blue ambient light in the first display region. Blue is a complementary color of yellow. Therefore, when the first display region is used as the photographing region, an impact from yellowish light of a mobile phone can be effectively prevented.

In an embodiment of the present disclosure, the display panel 00 further includes a dummy light-emitting unit located at a side of the light-emitting unit adjacent to a non-display region of the display panel. The color filtering layer further includes a third region. Along the first direction, the third region overlaps the dummy light-emitting unit. The third region includes at least overlapping color filter units of different colors. Located at an edge of the display region, the dummy light-emitting unit does not emit light actually. The overlapped color filter units in the third region are used for blocking to avoid anode reflection in the dummy light-emitting unit and avoid inconsistent reflection between the display region and the non-display region. Moreover, the third region is used for blocking to ensure an integrated black panel (IBP) effect and improve experience.

In an embodiment of the present disclosure, the display panel further includes the third-color color filter unit. The third-color color filter unit is the red color filter unit, and the second-color color filter unit is the green color filter unit. A thickness of the blue color filter unit is smaller than a thickness of the green color filter unit, while a thickness of the red color filter unit is smaller than the thickness of the green color filter unit.

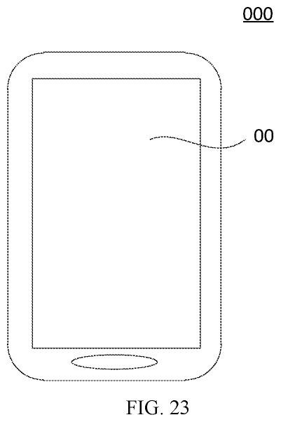

The present disclosure further provides a display apparatus. FIG. 23 is a schematic diagram of a display apparatus according to an embodiment of the present disclosure. The display apparatus 000 includes the display panel 00 provided in any embodiment of the present disclosure. The display apparatus provided in the present disclosure includes but is not limited to: a television, a notebook computer, a desktop display, a tablet computer, a digital camera, a mobile phone, a smart bracelet, smart glasses, a car camera, a medical device, an industrial control device, and a touch interactive terminal.

According to the above embodiments, the display panel and display apparatus provided in the present disclosure at least achieve following beneficial effects:

The display panel provided in the present disclosure includes a substrate, an array layer, a light-emitting layer, and a color filtering layer. A color filter unit includes a first-color color filter unit and a second-color color filter unit, and the first-color color filter unit is located at a side of the second-color color filter unit adjacent to the substrate. The first-color color filter unit is a blue color filter. On one hand, a color film layer is used to replace a traditional POL, which not only reduces a thickness of the display panel, but also increases light transmittance and enhances brightness of the entire display panel. On the other hand, the blue color filter is disposed on the side of the second-color color filter unit adjacent to the substrate. Compared with the second-color color filter unit, the blue color filter is preferentially coated, exposed, developed, and ultraviolet cured. Then, in a subsequent process of making the display panel, when the second-color color filter unit is ultraviolet cured, secondary ultraviolet irradiation can be performed on the blue color filter formed in an early stage. This can enhance film adhesion of the blue color filter, reduce a risk of generating a crack, shorten curing time of the blue color filter, and improve curing efficiency.

The present disclosure is described in further detail above with reference to the specific and preferred implementations, but the description should not be construed as a limitation to the specific implementation of the present disclosure. Several simple deductions and replacements can also be made by those skilled in the art without departing from the concept of the present disclosure, and all of these deductions and replacements fall within the protection scope of the present disclosure.

What is claimed is:

1. A display panel, comprising:
a substrate;
an array layer located at a side of the substrate;
a light-emitting layer located at a side of the array layer away from the substrate, the light-emitting layer comprising light-emitting units; and
a color filtering layer located at a side of the light-emitting layer away from the substrate, the color filtering layer comprising color filter units that correspond to the light-emitting units;
wherein the color filter units comprise a first-color color filter unit and a second-color color filter unit, and the first-color color filter unit is located at a side of the second-color color filter unit adjacent to the substrate; and
wherein the first-color color filter unit is a blue color filter unit.

2. The display panel according to claim 1, wherein the color filtering layer comprises first regions located between two adjacent ones of the light-emitting units;
along a first direction, at least overlapped color filter units of different colors are disposed in the first region; and
the first direction is a direction perpendicular to the substrate and pointing to a light exit surface of the display panel.

3. The display panel according to claim 2, wherein the light-emitting units comprises a first-color light-emitting unit, a second-color light-emitting unit and a third-color light-emitting unit that have different colors;
the color filter units further comprise a third-color color filter unit disposed corresponding to the third-color light-emitting unit;
the first region comprises overlapped color filter units of two colors, and the first region comprises a first sub-region located between the first-color light-emitting unit and the second-color light-emitting unit, and a second sub-region located between the first-color light-emitting unit and the third-color light-emitting unit; and
the first sub-region comprises overlapped first and second color sub-filters of different colors, and the second sub-region comprises overlapped third and fourth color sub-filters of different colors, wherein at least one of the first color sub-filter and the second color sub-filter has a same color as at least one of the third color sub-filter and the fourth color sub-filter.

4. The display panel according to claim 3, wherein the first color sub-filter has a same color as the first-color color filter unit, the second color sub-filter has a same color as the second-color color filter unit, the third color sub-filter has a same color as the first-color color filter unit, and the fourth color sub-filter has a same color as the third-color color filter unit.

5. The display panel according to claim 3, wherein the first color sub-filter has a same color as one of the first-color color filter unit and the second-color color filter unit, and the second color sub-filter has a same color as the third-color color filter unit; and/or
the third color sub-filter has a same color as one of the first-color color filter unit and the third-color color filter unit, and the fourth color sub-filter has a same color as the second-color color filter unit.

6. The display panel according to claim 3, wherein the first color sub-filter has a same color as the third color sub-filter, and the second color sub-filter has a same color as the fourth color sub-filter.

7. The display panel according to claim 3, wherein at least one of the first color sub-filter and the second color sub-filter is a red color filter unit; and/or
at least one of the third color sub-filter and the fourth color sub-filter is the red color filter unit.

8. The display panel according to claim 2, further comprising a touch layer, wherein the touch layer comprises touch lines located among the light-emitting units and overlapping the first region in the first direction; and
in the first region, an overlapping width of the color filter units of different colors is defined as d1, and a width of the touch lines is defined as d2, where d1>d2.

9. The display panel according to claim 1, wherein the first-color color filter unit comprises a first side surface and a first surface adjacent to the side of the substrate, and an angle formed between a tangent plane of at least a partial region of the first side surface and the first surface is greater than 90°.

10. The display panel according to claim 9, wherein the second-color color filter unit is a green color filter unit, the second-color color filter unit comprises a second side surface and a second surface adjacent to the side of the substrate, and an angle formed between a tangent plane of at least a partial region of the second side surface and the second surface is greater than 90°.

11. The display panel according to claim 2, wherein the color filter units further comprise a third-color color filter unit;
in the first direction, the first region comprises the first-color color filter unit, the second-color color filter unit, and the third-color color filter unit that are overlapped, the second-color color filter unit is a green color filter unit, and the third-color color filter unit is a red color filter unit; and
the blue color filter unit is located at a side of the green color filter unit adjacent to the substrate, and the red color filter unit is located at a side of the green color filter unit away from the substrate.

12. The display panel according to claim 2, further comprising a black matrix located at a side of the first-color color filter unit adjacent to the substrate, wherein along the first direction, the black matrix overlaps the first region.

13. The display panel according to claim 2, wherein the first region comprises the first-color color filter unit and the second-color color filter unit that are overlapped, and the first-color color filter unit is located at the side of the second-color color filter unit adjacent to the substrate; and
the first-color color filter unit comprises a first through-hole, the second-color color filter unit comprises a second through-hole, and an orthogonal projection of at least a part of the second through-hole on the substrate covers an orthogonal projection of the first through-hole on the substrate.

14. The display panel according to claim 13, wherein at least part of the second-color color filter unit is located within the first through-hole.

15. The display panel according to claim 2, wherein the first region comprises the first-color color filter unit and the second-color color filter unit that are overlapped, and the first-color color filter unit is located at a side of the second-color color filter unit adjacent to the substrate; and
the first-color color filter unit comprises a first through-hole, and the second-color color filter unit is a green color filter unit and covers the first through-hole.

16. The display panel according to claim 2, further comprising a first display region and a second display region, wherein a light transmittance of the first display region is greater than a light transmittance of the second display region, the first display region comprises the first region, and the second display region comprises the first region; and
an overlapping width of color filter units of different colors in the first region of the first display region is defined as D1, and an overlapping width of color filter units of different colors in the first region of the second display region is defined as D2, where D1<D2.

17. The display panel according to claim 2, further comprising a first display region and a second display region, wherein a light transmittance of the first display region is greater than a light transmittance of the second display region, and the first display region comprises wiring connection portions; and the color filtering layer further comprises a second region, at least overlapped color filter units of different colors are provided in the second region along the first direction, and an orthogonal projection of the second region on the substrate covers the wiring connection portion.

18. The display panel according to claim 17, wherein the second region comprises the first-color color filter unit and the second-color color filter unit that are overlapped, and the first-color color filter unit is located at the side of the second-color color filter unit adjacent to the substrate, wherein a width of the first-color color filter unit is greater than a width of the second-color color filter unit.

19. The display panel according to claim 1, further comprising a dummy light-emitting unit located at a side of the light-emitting units adjacent to a non-display region of the display panel, wherein the color filtering layer further comprises a third region; and
along the first direction, the third region overlaps the dummy light-emitting unit, and the third region comprises at least overlapped color filter units of different colors.

20. A display apparatus, comprising a display panel, wherein the display panel comprises:
a substrate;
an array layer located at a side of the substrate;
a light-emitting layer located at a side of the array layer away from the substrate, the light-emitting layer comprising light-emitting units; and
a color filtering layer located at a side of the light-emitting layer away from the substrate, the color filtering layer comprising color filter units that correspond to the light-emitting units;
wherein the color filter units comprise a first-color color filter unit and a second-color color filter unit, and the first-color color filter unit is located at a side of the second-color color filter unit adjacent to the substrate; and
wherein the first-color color filter unit is a blue color filter unit.
